(19) United States
(12) Patent Application Publication
(10) Pub. No.: US 2010/0132766 A1
(43) Pub. Date: Jun. 3, 2010

(54) STRUCTURAL ATTACHMENT OF SOLAR MODULES TO FRAMES BY GLAZING

(75) Inventor: Stephen M. Jenkins, Bay City, MI (US)

Correspondence Address: REISING ETHINGTON P.C., P O BOX 4390, TROY, MI, 48099-4390, US

(73) Assignee: DOW CORNING CORPORATION, Midland, MI (US)

(21) Appl. No.: 12/520,943

(22) PCT Filed: Dec. 26, 2007
(86) PCT No.: PCT/US07/88833

§ 371 Date: Jan. 27, 2010

Related U.S. Application Data
(60) Provisional application No. 60/877,306, filed on Dec. 27, 2006.

(51) Int. Cl. H01L 31/048; H01L 21/50

(52) U.S. Cl. 136/251; 438/64; 257/E21.499

(57) ABSTRACT

A solar module and method of making same is provided. The assembly includes a solar module. A frame having a support surface for supporting the solar module is provided. A structural sealant is disposed between the solar module and the frame for structurally securing the solar module to the frame. The structural sealant comprises a silicone-containing structural adhesive, a structural adhesive tape, or a hot melt sealant. The frame comprises a metal, plastic, composite material or combinations thereof. The frame is preassembled to form a integral frame before the solar module is attached. The frame may include an opening for accommodating electrical components.

### CROSS-REFERENCE TO RELATED APPLICATION

The instant application claims priority to U.S. Provisional Application Ser. No. 60/877,306 filed 27 Dec. 2006, the entire specification of which is expressly incorporated herein by reference.

### FIELD OF THE INVENTION

The present invention relates to a solar module assembly and method for making the same. More particularly, the present invention relates to the use of a structural sealant to secure a solar module to a frame.

### BACKGROUND OF THE INVENTION

Currently, frames for solar panels or modules typically comprise a four-piece pre-cut aluminum frame extrusion which forms a mechanical restraint upon the glass laminate. The extrusions typically include a c-shape channel that is used to mechanically restrain the solar panel. The four frame pieces are then pressed at the c-shaped channel onto the solar panel and the frame corners attached with screws or corner keys. Cushioning materials are typically placed between the laminate and the frame to help cushion the inner face of the laminate and frame. The cushioning material has little structural value. The cushioning material is typically dispensed (in the case of a hot melt or sealant) or attached (in the case of a double sided cushioning tape) to the panel for insertion into the c-shaped channel. The cushioning material serves to help protect the edge of the laminate from directly contacting the frame.

This type of framing system for solar modules suffers from several drawbacks. For example, the extruded members comprise relatively expensive, complex-shaped anodized aluminum profiles. Further, long assembly times are required to handle the multiple frame pieces during assembly with the solar module. Also, because the frame is limited to rectangular configurations, there is limited ability to mount the solar panels in various configurations. Long cure times are often required for the cushioning sealant before the solar panel assembly can be moved after assembly. Additionally, these framing systems do not allow for mounting of an untrimmed module. Typically a solar module undergoes a time consuming process known as trimming where excess laminating material, i.e., melted encapsulant that is squeezed out and excess backsheet, are cut away from the edges of the glass superstrate.

U.S. Pat. No. 7,012,188 to Earling shows a framing system for solar panels. The framing system incorporates the c-shape design for restraining the laminate as described above. The assembly includes a channel which accommodates a solar tile laminate that is sealingly engaged in a polymeric channel shaped seal.

Another example of a solar power module is shown in U.S. Pat. No. 4,392,009 to Napoli. This reference also shows a c-shaped channel for receiving the solar panel or laminate. The panel is disposed between two opposing flanges which protrude from the channel to form the c-shaped receptacle.

Japanese Patent Application JP2002289892A also discloses a Solar Battery Module.

### SUMMARY OF THE INVENTION

According to one embodiment, there is provided a solar module assembly comprising a solar module. The assembly further comprises a frame having a support surface for supporting the solar module. The assembly further comprises a structural sealant disposed between the solar module and the frame for structurally securing the solar module to the frame. The structural sealant contains silicone.

According to one embodiment, there is provided a solar module assembly comprising a solar module. The assembly further comprises a one-piece frame having a support surface for supporting the solar module. A structural sealant is disposed between the solar module and the frame for structurally securing the solar module to the frame.

According to one embodiment, there is provided a solar module assembly comprising a solar module. The solar module comprises a superstrate, a backing and at least one solar cell between the glass superstrate and the backing. The assembly further comprises a frame. The frame comprises a support surface for supporting the solar module and a guard transverse to the support surface. The assembly further comprises a structural sealant disposed between the superstrate and the support surface for structurally securing the solar module to the frame.

According to one embodiment of the present invention, there is provided a method of making a solar module assembly. The method comprises providing a solar module having a superstrate, a backing and at least one solar cell between the superstrate and the backing. The method further comprises forming an integral frame having a support surface for supporting the solar module. A structural sealant is placed on the surface and the solar module is placed on the structural sealant to thereby secure the solar module to the frame.

### BRIEF DESCRIPTION OF THE DRAWINGS

FIG. 1 is an exploded perspective view of one embodiment of the present invention;

FIG. 2 is an exploded cross-sectional view taken along lines 2-2 of FIG. 1;

FIG. 3A is a cross-sectional view of an alternate frame according to another embodiment of the present invention;

FIG. 3B is a cross-sectional view of an alternate frame according to another embodiment of the present invention;

FIG. 3C is a cross-sectional view of an alternate frame according to another embodiment of the present invention;

FIG. 3D is a cross-sectional view of an alternate frame according to another embodiment of the present invention;

FIG. 3E is a cross-sectional view of an alternate frame according to another embodiment of the present invention;

FIG. 3F is a cross-sectional view of an alternate frame according to another embodiment of the present invention;

FIG. 4A is a cross-sectional view partially broken away of an alternate embodiment of the present invention;

FIG. 4B is a cross-sectional view partially broken away of an alternate embodiment of the present invention;

FIG. 4C is a cross-sectional view partially broken away of an alternate embodiment of the present invention, schematically showing one method of manufacturing the embodiment;

FIG. 5 is a perspective view of an alternate frame according to another embodiment of the present invention;

FIG. 6 is a plan view partially broken away of an alternate frame according to another embodiment of the present invention incorporating a junction box;

FIG. 7 is a cross-sectional view, partially broken away of an alternate embodiment of the present invention; and

FIG. 8 is an exploded perspective view of another embodiment of the present invention.

### DETAILED DESCRIPTION OF THE PREFERRED EMBODIMENT

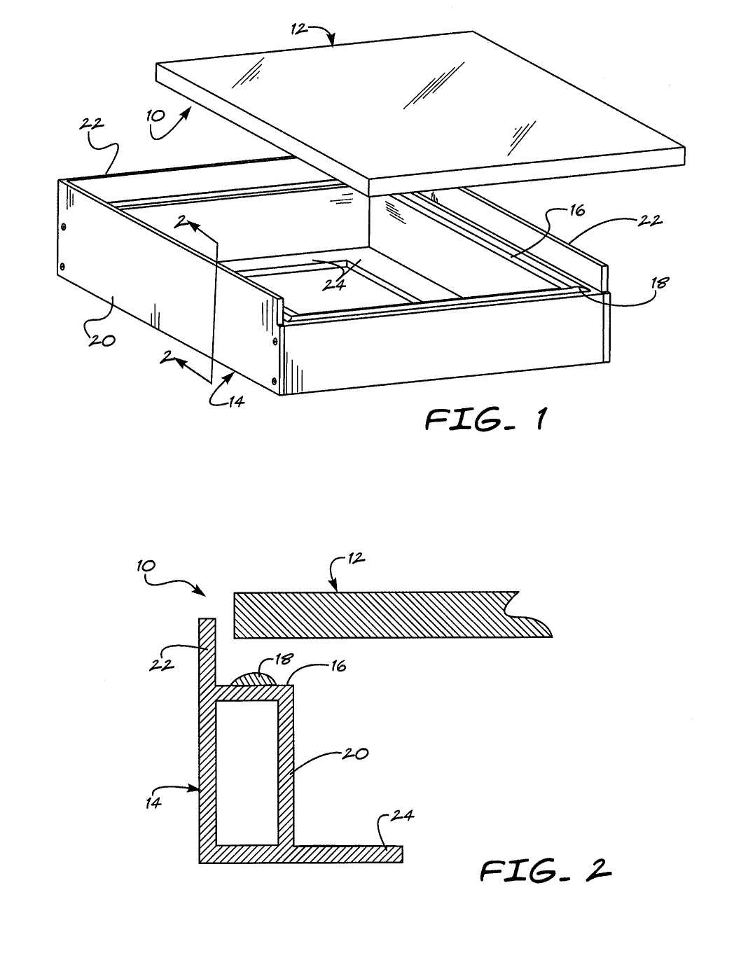

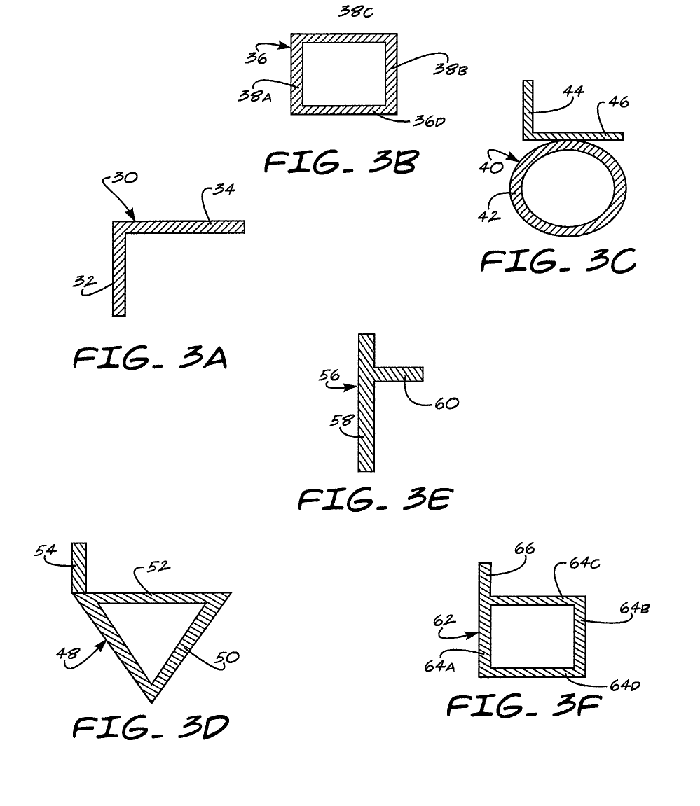

As used herein, like reference numbers will be used to represent like parts throughout the various embodiments. FIG. 1 shows an exploded perspective view of one embodiment of the present invention. FIG. 2 shows an exploded cross-sectional view of the embodiment shown in FIG. 1. A solar module assembly is generally shown at 10 in FIGS. 1 and 2. The solar module assembly 10 includes a solar module generally indicated at 12. The solar module assembly 10 further includes a frame generally indicated at 14. The frame 14 includes a support surface 16 for supporting the solar module 12. The solar module assembly 10 further includes a structural sealant 18 disposed between the solar module 12 and the frame 14 for structurally securing the solar module 12 to the frame 14.

Solar cells or photovoltaic cells are often electrically connected and encapsulated and mounted in a frame to form a module. Solar modules often have a sheet of glass on the side exposed to the sun (superstrate) onto which the solar cells are mounted. A protective resin barrier is placed behind the solar cells. Thus, the solar module includes a glass superstrate, a protective resin barrier or backing and at least one solar cell between the superstrate and the barrier to provide a laminate structure as is known in the art. It will be appreciated that while glass is preferred, any suitable superstrate may be used. This assembly is then mounted in a frame. Solar cells are typically electrically connected to form a module. Modules are then electrically interconnected to create a solar panel or array. As will be used herein, the term solar module is intended to refer to solar modules, solar panels or solar arrays which refer to the unframed, assembled, usually laminated, structure of the solar cells, electrical connections, encapsulants and protective backing on any superstrate or substrate.

As shown in FIGS. 1 and 2, the solar module 12 is adapted to be secured to a frame 14. In the embodiment shown, the frame 14 comprises a plurality of a generally rectangular tubular frame members 20 secured together to form an integral frame. A top surface 16 of the tubular member 20 comprises a support surface 16 for supporting the solar module 12. The frame members 20 may include a guard 22 extending upwardly from and integral with the tubular member 20. The guard 22 provides protection to the edge of the solar module 12. The guard aids in protecting the edge of the solar module 12, and particularly the edge of the superstrate, typically glass, that forms a part of the module 12.

The frame members 20 may further include a flange 24 integral with and extending from the frame member 20. The flange 24 may provide support to the frame 14. Further the flange 24 may provide an attachment surface. That is, the flange 24 may be used to secure the solar module assembly to a support structure.

Further, electrical componentry, such as junction boxes (not shown) or the like may be secure to the flange 24.

The frame 14 may be made of any suitable material. By way of non-limiting example, the frame may be made of a metal including, for example, aluminum. The aluminum may be surface treated against corrosion. Additionally, by way of non-limiting example, the frame 14 may be made of any suitable plastic or composite material. Additionally, the frame 14 may be made out of any combination of materials. Further, the frame may be made by any suitable forming process. By way of non-limiting example, the individual frame members 20 may be extruded or molded and then secured. Alternatively, the entire frame 14 may be integrally formed such as by molding. Because the frame 14 can be made of any materials, it is capable of being made in various colors and surface finishes.

As set forth in FIG. 1, four frame members 20 are shown. The frame members 20 are secured together in any suitable manner, such as by way of non-limiting example, the use of screws, corner keys, clips or the like. In one embodiment of the invention, the frame members are assembled before the solar module is adhered to form a unitary, integral frame to improve the assembly process. The frame members 20 include the support surface 16 for supporting the solar module 12. As shown, only some of the frame members 20 include the guard 22. While often desirable, it is not always necessary to protect the edges of the solar module 12. In some instances it may be desirable to leave the edges of the solar module 12 unprotected. Such an instance might occur to allow debris, snow, ice or rain to run off the unprotected edge when the assembly 10 is used. That is, typically, the solar module assembly 10 will be angled relative to the horizontal during use to optimize the efficiency of the solar module assembly 10. In such a case, the edge located closest to the ground may not be protected to allow any debris, snow, ice, rain or the like to more freely run off of the top of the solar module 12 without being restrained by any portion of the guard 22. In some instances, it may be desirable to add a restraining device, such as by way of example, a clip or other restraining device or frame feature may be added to the edge closest to the ground to further secure the solar module 12 and reduce shear forces on the adhesive material and underlying substrate.

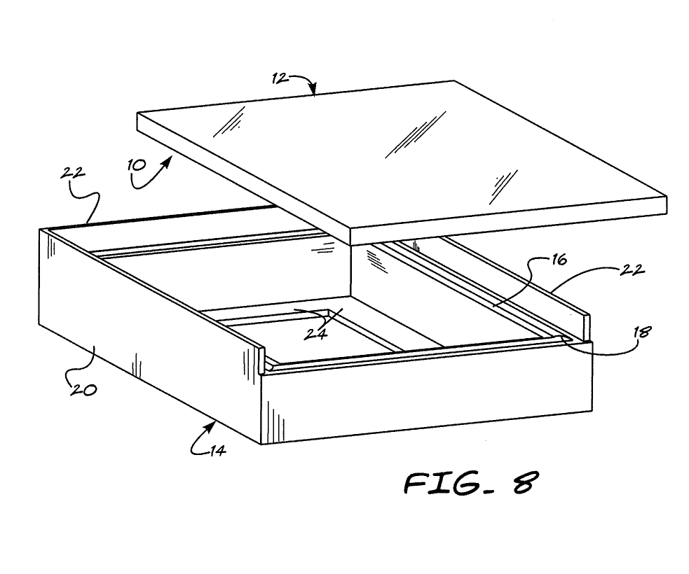

In another embodiment, as shown in FIG. 8, the frame 14 comprises a one-piece frame. Otherwise, the frame 14 is the same as that shown in FIG. 1 and like numbers are used to represent the like components. The frame members 20 may be integrally molded, preferably from a plastic or composite material, to form an integral, one-piece frame 14. In this embodiment, the support surface 16 for supporting the solar module 12, the frame members 20, guard 22 and flange 24 are all formed as one-piece by any suitable manufacturing process, such as by molding.

It will be appreciated that the guard 22 and flange 24 are optional and need not be included. Further, the frame members 20, guard 22 and flange 24 may comprise any suitable geometric configuration. It will be appreciated that in an embodiment where the frame is molded, it would be more accurate to describe a single frame member 20 having a plurality of different sections because there is only one frame member. For example, such a frame member, in a rectangular embodiment, would include four frame sections - the four sides to the rectangle. As used herein, the frame members refer to individual frame members when the frame is of the type comprising multiple pieces assembled together to form an integral frame or to the frame sections when the frame is of the type that is molded to form a one-piece frame.

By using a one-piece frame 14, or a preassembled frame 14, the frame 14 can be preassembled as a unitary, integral frame prior to adhering the solar module 12 to the frame and need not be made as multiple pieces secured together during the process of adhering the solar module 12 to the frame. This improves the manufacturing of the frame by eliminating the need to assemble individual frame members while also securing the frame to the solar module. Further, by molding the frame 12, one can incorporate additional features into the frame 14. By way of non-limiting example, attachment, architectural or decorative features can be molded into the frame 14. Thus the use of a one-piece molded frame 14 allows the ability to provide a frame 14 of virtually any shape and having accessories at suitable locations.

The use of a unitary frame 14 with a structural sealant 18, as described below, allows for an improved assembly process for providing a solar module assembly 10. Such an assembly reduces manufacturing time of the solar module assembly 10 and aids in reducing the cost of manufacturing.

As set forth above, the solar module assembly 10 includes a structural sealant 18 disposed between the solar module 12 and the frame 14 for structurally securing the solar module 12 to the frame 14. The structural sealant 18 can comprise any structural sealant composition useful to structurally secure the solar module 12 with the frame 14, independent of mechanical restraint. Structural sealants can include, but are not necessarily limited to, structural adhesives, structural adhesive tape and hot melt structural sealants. It will be appreciated that the structural sealant 18 that is used should preferably meet solar industry module loading and age testing requirements such as those specified in UL 1703 or IEC 61215. In one embodiment, silicone-containing structural adhesives are used as the structural sealant. Silicone adhesives comprise a structural material that add strength to the assembly 10 and aid in allowing the assembly 10 to pass loading test standards as specified above.

Silicone adhesives also offer effectiveness over a wide temperature range to which the assembly 10 may be subjected.

By way of non-limiting example, suitable structural adhesive compositions include acrylics, polyurethanes, epoxies, and silicones such as condensation reaction curable structural silicone compositions. Examples of structural silicone compositions include those commercially available from Dow Corning Corporation of Midland, Michigan under the names DOW CORNING® 795, DOW CORNING® 983 and DOW CORNING® 995 and those available from Dow Corning S.A. of Seneffe, Belgium, including DOW CORNING® 895, DOW CORNING® PV804 and DOW CORNING® 993. Other suitable structural silicone compositions are disclosed in U.S. Pat. Nos. 5,983,593 and 5,051,455, which are hereby incorporated by reference. It will be appreciated, however, that any other suitable structural adhesive may be used in the context of the present invention.

In one embodiment, structural adhesives containing silicone are used as the structural sealant. Silicone adhesives comprise a structural material that add strength to the assembly 10 and aid in allowing the assembly 10 to pass loading test standards as specified above. Silicone adhesives also offer effectiveness over a wide temperature range to which the assembly 10 may be subjected.

By way of non-limiting example, suitable structural adhesive tapes include an acrylic foam tape including a silicone foam support and a curable adhesive composition applied on opposing sides of the silicone foam support. Such adhesive tapes are disclosed for example in Pending PCT Application Nos. PCT/US06/026398 and PCT/US06/026387. It will be appreciated, however, that any other suitable structural adhesive tape may be used in accordance with the present invention.

By way of non-limiting example, suitable hot melt structural adhesives include those commercially available Dow Corning Corporation of Midland, Mich., under the names of DOW CORNING® InstantGlaze and DOW CORNING® InstantSeal. It will be appreciated, however, that any other suitable structural adhesive may be used in the context of the present invention.

In order to make a solar module assembly 10, a solar module 12 is provided. A frame 14 having a surface 16 for supporting the solar module 12 is also provided. The frame 14 is preassembled or molded as one piece. A structural sealant 18 is placed on the surface 16. The solar module 12 is then placed on the structural sealant 18. The protective resin barrier or backing of the solar module 10 contacts the structural sealant 18. The structural sealant 18 is allowed to cure or set, if necessary, to thereby structurally secure the solar module 12 to the frame 14.

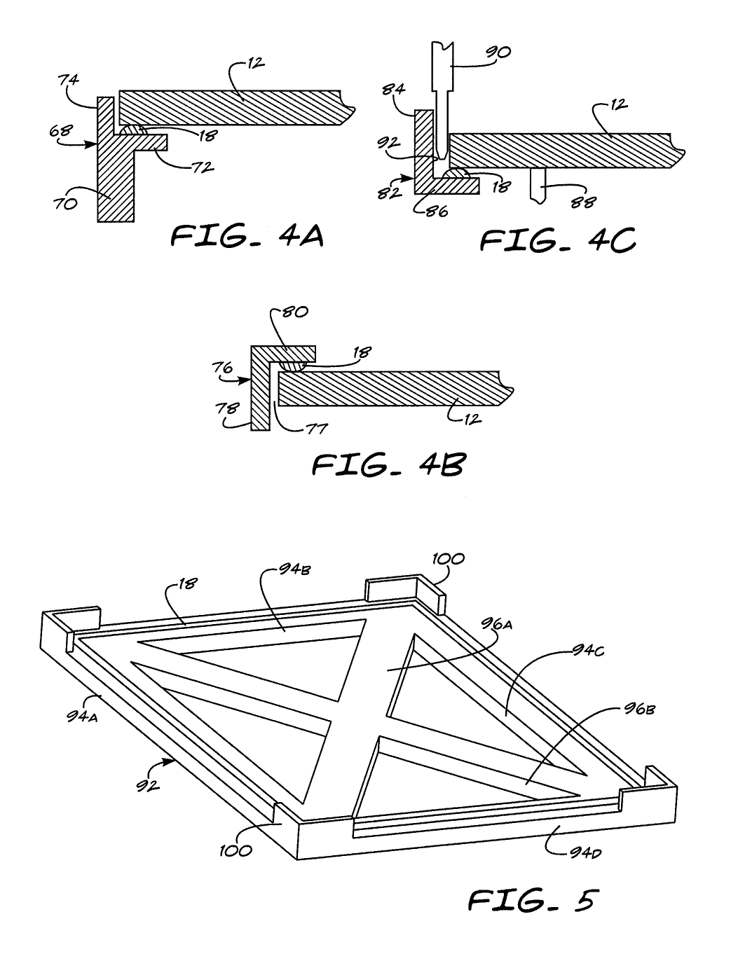

The structural sealant 18 can be placed on the surface 16 in any suitable manner. In the case of structural adhesives and hot melt structural adhesives, the structural sealant 18 can be dispensed via a suitable applicator onto either the surface 16 of the frame 14 or onto the edges of the solar module 12 that overlie the surface 16. It is most preferred that the structural sealant be placed on the surface 16 of the frame 14. In the case of structural adhesive tape, the tape can be applied first onto either the surface 16 of the frame 14 or onto the edges of the solar module 12 that overlie the surface 16. After the structural sealant 18 is applied to either the solar module 12 or surface 16, the solar module 12 can then be placed onto the surface 16 of the frame 14 as shown by the arrow in FIG. 2. Typically, the weight of the solar module 12 is sufficient to set the solar module into the structural sealant 18. In some instances pressure may also be applied to the solar module 12 to set the solar module 12 into the structural sealant 18. This is often the case when the frame surface to which the solar module 12 is secured is located above the solar module, as is the case for the embodiment as shown in FIG. 4B and described below.

The aforementioned process results in the glazing of the solar module 12 with the frame 14. That is, the solar module 12 is secured to the frame 14 without the necessity of mechanically retaining structures. Because the necessity of mechanically retaining the solar module 12 is eliminated by the glazing process, the variety of frame configurations that can be used is significantly increased. All that is necessary is that the frame 14 provides a suitable surface 16 to which the solar module 12 can be secured. In most instances it would be preferable that the surface be flat, such as the surface 16 in FIG. 2. However, it will be appreciated that the surface to which the solar module 12 is to be secured may be other than flat. For example, the frame 14 can have a round cross-section.

FIGS. 3A through 3F show various cross-sectional views of alternate frame members according to various embodiments of the present invention. FIG. 3A is a cross-sectional view of a frame member generally indicated at 30. The frame member 30 comprises a generally L-shaped member. A side 32 is integral with a transverse leg 34. The leg 34 supports a solar module 12. Because structural sealants are used to secure the solar module 12 with the frame member 30, the solar module 12 can be supported on either the top surface or the bottom surface of the transverse leg 34. When the solar module 12 is supported on the top surface of transverse leg 34, the edge of the solar module 12 is not protected by the frame member 30. When the solar module 12 is supported on the bottom surface of the transverse leg 34, the edge of the solar module 12 is protected by the side 32.

FIG. 3B is a cross-sectional view of a frame member generally indicated at 36. The frame member 36 comprises a generally tubular member having a rectangular cross-section. The frame member 36 has two side surfaces 38a and 38b, a top surface 38c and a bottom surface 38d. The solar module 12 can be supported on either the top surface 38c or the bottom surface 38d.

FIG. 3C is a cross-sectional view of a frame member generally indicated at 40. The frame member 40 comprises a generally tubular member 42 having a round cross-section. An L-shaped frame member 44 is secured to the tubular member 42. The L-shaped member 44 has a surface 46 for supporting the solar module 12.

FIG. 3D is a cross-sectional view of a frame member generally indicated at 48. The frame member 48 comprises a generally tubular member 50 having a triangular cross-section. The solar module 12 is supported on a flat top surface 52 of the tubular member 50. A guard 54 extends from the tubular member 50 to protect the edge of the solar module 12.

FIG. 3E is a cross-sectional view of a frame member generally indicated at 56. The frame member 30 comprises a side 58 and a leg 60 extending transversely to the side 58. The leg 60 supports a solar module 12. The solar module 12 can be supported on either the top surface or the bottom surface of the transverse leg 60. When the solar module 12 is supported on either of the top surface or bottom surface of transverse leg 60, the edge of the solar module 12 is protected by the side 58.

FIG. 3F is a cross-sectional view of a frame member generally indicated at 62. The frame member 62 comprises a generally tubular member having a rectangular cross-section. The frame member 62 has two side surfaces 64a and 64b, a top surface 64c and a bottom surface 64d. A guard 66 extends upwardly from top surface 64c. The solar module 12 can be supported on either the top surface 64c or the bottom surface 64d. When the solar module 12 is supported on the top surface 64c, the edge of the solar module 12 is protected by the guard 66. When the solar module 12 is supported on the bottom surface 64d, the edge of the solar module 12 is not protected.

As can be seen from, for example, FIGS. 3A through 3F, the design of the frame can take virtually any configuration. It is necessary that the frame have some surface for supporting the solar module 12. Additionally, the frame can comprise any material that will adhere to the structural sealant. The frame can be made using any suitable manufacturing technique, such as extrusion or molding. If the frame members are made individually, they can be connected in any manner to produce any shape. Typically, four frame members are interconnected in a rectangular shape to form a frame to which the solar module 12 is secured. It will be appreciated, however, that the frame member need not be interconnected.

FIG. 4A is a cross-sectional view, partially broken away, of an alternate embodiment of the present invention. In this embodiment, the frame member is generally indicated at 68. The frame member 68 has a lower portion 70. A leg 72 extends transversely to the lower portion 70. A guard 74 extends upwardly from the lower portion 68. As shown, a suitable structural sealant 18 is disposed on an upper surface of the leg 72. The solar module 12 is disposed on the structural sealant 18. In this embodiment, the edge of the solar module 12 is protected by the guard 74.

FIG. 4B is a cross-sectional view partially broken away of an alternate embodiment of the present invention. In this embodiment, the frame member is generally indicated at 76. The frame member 76 comprises a generally L-shaped member. A side 78 is integral with a transverse leg 80. The leg 80 supports a solar module 12 on the bottom surface thereof. That is, the structural sealant 18 is applied to the bottom surface of the leg 80. The solar module 12 is then secured to the structural sealant to secure the solar module 12 with the frame member 76. In this arrangement, the structural sealant 18 contacts the glass superstrate of the solar module 12. This arrangement may be beneficial in some instances in that by having the contact between the structural sealant 18 and the glass superstrate of the solar module 12, stresses may be reduced between the framing material and the solar module 12. The frame-to-glass construction can better withstand the thermal expansion mismatches between the various components as the assembly 10 is exposed to various atmospheric conditions. This may be particularly effective when the frame 14 comprises fiberglass.

Because the solar module 12 is supported on the bottom surface of the transverse leg 80, the edge of the solar module 12 is protected by the side 78. Thus, the side 78 comprises a guard for the edge of the solar module 12. FIG. 4B also shows a space 77 between the module 12 and the side 78. The space 77 can be sized to allow for mounting of an untrimmed module. While shown in the context of the embodiment shown in FIG. 4B, the space for allowing the mounting of an untrimmed module can be incorporated into many different frame designs. Further, the space 77 may, in some instances be filled completely or partially with a water barrier and/or edge sealant material (not shown) that can aid in preventing water ingress between the solar module 12 and the frame 14. This helps minimize degradation of the solar cells and improves the life of the assembly 10 by preventing water and water vapor ingress through the edge of the solar module laminate. A suitable water barrier and/or edge sealant may comprise a silicone, butyl, or other flowable, curable, or hot melt elastomeric barrier sealant.

FIG. 4C is a cross-sectional view, partially broken away, of an alternate embodiment of the present invention, schematically showing one method of manufacturing the embodiment. In this embodiment, the frame member is generally indicated at 82. The frame member 82 comprises a generally L-shaped member. A side 84 is integral with and extends upwardly from a transverse leg 86. The leg 86 supports the solar module 12 on the top surface thereof.

FIG. 4C schematically shows alternate method of manufacturing the solar module assembly. Here, the solar module 12 is supported by suitable supports 88 at a position above the leg 86. The side edge of the solar module 12 is spaced from the side 84 sufficiently to allow an applicator to be inserted between the side 84 and the solar module 12. A suitable applicator 90 is inserted into the space 92 between the side edge of the solar module 12 and the side 84. Structural sealant 18 is then applied from the applicator 90 between the solar module 12 and the top surface of the leg 86. The supports 88 are then removed to allow the solar module 12 to contact the structural sealant. In this manner, the solar module is structurally secured with the frame members 82. This method is particularly useful when a hot melt structural sealant is used.

FIG. 5 is a perspective view of an alternate frame according to another embodiment of the present invention. In this embodiment, the frame is generally indicated at 92. The frame 92 comprises four side members 94a, 94b, 94c and 94d. Brace members 96a and 96b extend intermediate the four side members 94a, 94b, 94c and 94d. Here, the brace members 96a and 96b intersect to form an X-pattern between the four side members 94a, 94b, 94c and 94d. Top surfaces of each of the four side members 94a, 94b, 94c and 94d and brace members 96a and 96b provide a surface 98 for supporting the solar module 12. In this manner, the frame 92 supports the solar module 12 on the surface 98 thereof with an arrangement that is independent of an edge seal or guard. As shown in FIG. 5, the structural sealant is placed around the peripheral edges of top surfaces of each of the four side members 94a, 94b, 94c and 94d. Additionally, while not necessary in all applications, structural sealant 18 may be placed on any of the brace members 96a and 96b (not shown) to additionally secure the solar module 12 with the frame 92.

In the embodiment shown in FIG. 5, the frame 92 further includes corner guards 100. The corner guards 100 extend outwardly from a portion of the top surfaces of the side members 94a, 94b, 94c and 94d at the corners thereof. The corner guard 100 can be used to guard the edges of the solar module 12.

It will be appreciated that the frame 92 may be made in suitable manner. For example, each of the side members 94a, 94b, 94c and 94d and the brace members 96a and 96b may be fabricated independently, such as by way of non-limiting example, by extrusion and secured together in any suitable manner. Alternatively, the frame 92 may be integrally made, such as by way of non-limiting example, by molding. Additionally, as set forth above, the frame 92 can be made out of any suitable material.

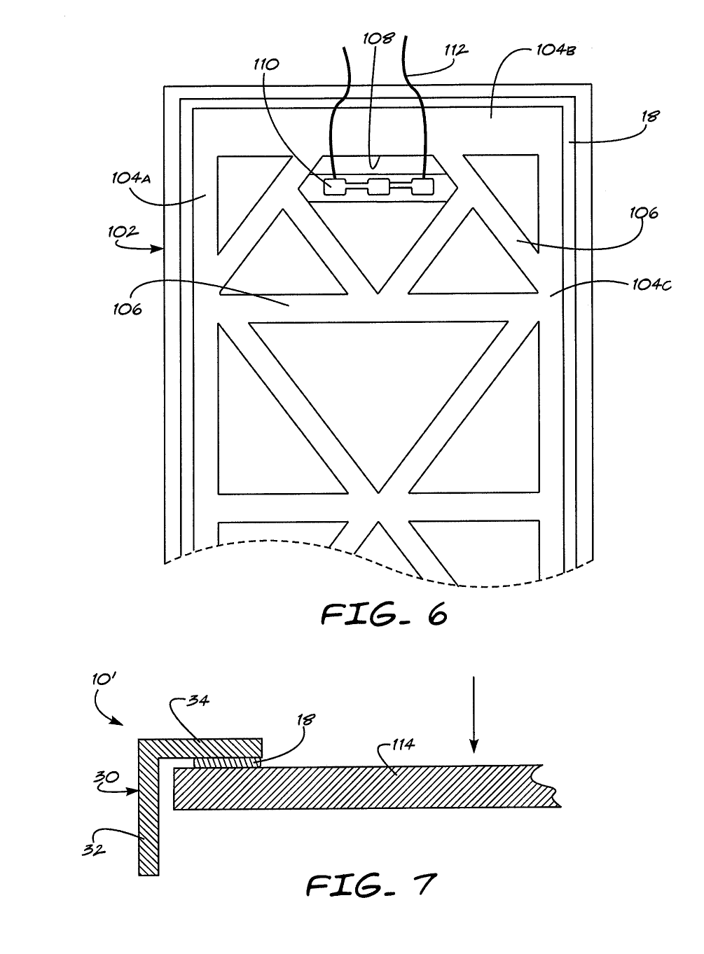

FIG. 6 is a plan view partially broken away of an alternate frame generally indicated at 102 according to another embodiment of the present invention. The frame 102 comprises four side members, three of which, 104a, 104b and 104c are shown. A series of brace members 106 extend intermediate the side member 104a, 104b and 104c. The brace members 106 can be arranged in any manner. As shown, the brace members 106 extend in a manner so as to provide generally triangular braces intermediate the side members 104a, 104b and 104c. The brace members define an opening 108 that can be used to mount additional structure to the solar module assembly. For example, the opening 108 may be used to house electrical components 110. In this manner, the frame 102 incorporates the function of a junction box typically required in solar module assemblies. A junction box is an electrical connection box typically mounted on the backside of the solar module which serves to connect the inner wiring of the module to the outer wiring or cords that typically connect one solar module to the next in an array. Typically, junction boxes are made of a plastic material and may contain not only metal electrical tabbing and connectors, but also electrical diodes or other componentry to control the direction of electrical current flow coming from the module. In the embodiment shown in FIG. 6, the function of the junction box is integrated into the frame 102 between various side members 104b and brace members 106. Electrical componentry 110 is housed in the opening 108. Wires 112 extend outwardly therefrom.

In the FIG. 6 embodiment, the structural sealant 18 can be placed on the top surfaces of the side members 104a, 104b and 104c near the peripheral edges, as shown in FIG. 6. It will be appreciated that the structural sealant can also be applied to the top surfaces of the brace members 106 if desired (not shown). The solar module 12 can then be placed on top of the structural sealant 18 to structurally secure the solar module with the frame 102.

FIGS. 5 and 6 show frames having various designs for support braces that support the back of the solar module 12. It will be appreciated that the support braces can be arranged in any suitable pattern. Similarly, the frame need not be generally rectangular as shown. Because of the flexibility in the design of the frame according to the present invention, a variety of shapes can be achieved by using assembled or molded metal, plastic or composite materials.

An example of a solar module assembly 10′ in accordance with the present invention was made and tested. For purposes of the test, the solar module 12 was replaced with a sheet of tempered glass 114 of the type typically used as a superstrate for a solar module mounted on an aluminum L-shaped frame 30. The frame 30 is of the type shown in FIG. 7. Structural sealant 18, in the form of a structural adhesive tape was applied to the bottom side of leg 34 for supporting the glass panel 114. The dimensions of the sheet of glass 114 were 20.5 in.×46.5 in. The sheet of glass was mounted into a frame that was 21 in.×47 in. The leg 34 measured ¼ in.×½ in.

The assembly was placed onto a table and the glass surface loaded (L) with weights. There was no failure of the adhesive bond. The assembly was aged in a climatic chamber. The results of the test are set forth in Table 1 below.

TABLE 1

| | Amount of | Calculated Pounds | Calculated Pounds |
|---|---|---|---|
| Condition of | Weight | Per Square Inch | Per Square Feet Of |
| Sample | Applied | On Wetted Area | Glass Surface |
| Within first hour | 200 pounds | 6 lbs/in² | 30 lbs/ft² |
| of construction | | | |
| After 48 hours | 424 pounds | 13 lbs/in² | 64 lbs/ft² |
| After 1000 hours in | 845 pounds | 25 lbs/in² | 126 lbs/ft² |
| damp heat 85 C./85% | | | |
| relative humidity | | | |

By using a solar module assembly of the type described hereinabove, any number of framing styles, profiles, and materials can be used. These designs are unconstrained by the previous need for mechanical restraint of the edges of the solar module. Further, because there is no need to mechanically restrain the solar module by the frame, the frame need not support every edge of the solar module. For example, it may, in certain instances, be desirable to have the frame support less than every edge of the solar module.

By using a solar module assembly of the type described hereinabove, the solar module assembly provides greater flexibility in how the solar module assembly can be installed for use. The solar modules can be supported on many additional locations during use than were possible with prior mechanically restrained fixing systems.

The invention has been described in an illustrative manner. It is to be understood that the terminology used is intended to be in the nature of words of description. Obviously many modifications and variations are possible in light of the above teachings. It is therefore to be understood that the invention set forth in the claims may be practiced other than as specifically described.

What is claimed is:

1. A solar module assembly comprising:
a solar module;
a frame having a support surface for supporting the solar module;
a structural sealant disposed between the solar module and the frame for structurally securing the solar module to the frame, wherein the structural sealant contains silicone.

2. A solar module assembly as set forth in claim 1 wherein the structural sealant comprises a structural adhesive.

3. A solar module assembly as set forth in claim 1 wherein the structural sealant comprises a structural adhesive tape.

4. A solar module assembly as set forth in claim 1 wherein the structural sealant comprises hot melt sealant.

5. A solar module assembly as set forth in claim 1 wherein the support surface is flat.

6. A solar module assembly as set forth in claim 5 further comprising a projection extending from and transversely to the support surface.

7. A solar module assembly as set forth in claim 1 wherein the frame comprises at least a pair of frame members.

8. A solar module assembly as set forth in claim 7 wherein the frame further comprises at least one brace member extending intermediate the at least a pair of frame members.

9. A solar module assembly as set forth in claim 8 wherein the solar module includes an electrical component and the at least one brace member defines an opening for receiving at least some of the electrical component.

10. A solar module assembly as set forth in claim 7 wherein the frame is made of a material from the group consisting of metals, composites, plastics and combinations thereof.

11. A solar module assembly as set forth in claim 7 wherein the frame is molded to form a one-piece frame.

12. A solar module assembly as set forth in claim 1 wherein the solar module comprises a superstrate, a backing and at least one solar cell disposed between the superstrate and the backing, the structural sealant disposed between the support surface and the superstrate.

13. A solar module assembly comprising:
a solar module;
a one-piece frame having a support surface for supporting the solar module;
a structural sealant disposed between the solar module and the one-piece frame for structurally securing the solar module to the frame.

14. A solar module assembly as set forth in claim 13 wherein the structural sealant comprises a structural adhesive.

15. A solar module assembly as set forth in claim 14 wherein the structural adhesive is selected from the group consisting of: acrylics, polyurethanes, epoxies, silicones and combinations thereof.

16. A solar module assembly as set forth in claim 13 wherein the structural sealant comprises a structural adhesive tape.

17. A solar module assembly as set forth in claim 13 wherein the structural sealant comprises hot melt sealant.

18. A solar module assembly as set forth in claim 13 wherein the one-piece frame is molded.

19. A solar module assembly as set forth in claim 18 wherein the one-piece frame is made of a material from the group consisting of metals, composites, plastics and combinations thereof.

20. A solar module assembly as set forth in claim 13 wherein the support surface is flat.

21. A solar module assembly as set forth in claim 13 further comprising a projection extending from and transversely to the support surface.

22. A solar module assembly as set forth in claim 13 wherein the one-piece frame comprises at least a pair of frame members.

23. A solar module assembly as set forth in claim 22 wherein the one-piece frame further comprises at least one brace member extending intermediate the at least a pair of frame members.

24. A solar module assembly as set forth in claim 23 wherein the solar module includes an electrical component and the at least one brace member defines an opening for receiving at least some of the electrical component.

25. A solar module assembly as set forth in claim 13 wherein the solar module comprises a superstrate, a backing and at least one solar cell disposed between the superstrate and the backing, the structural sealant disposed between the support surface and the superstrate.

26. A solar module assembly comprising:
a solar module comprising a superstrate, a backing and at least one solar cell between the superstrate and the backing;
a frame comprising a support surface for supporting the solar module and a guard transverse to the support surface;
a structural sealant disposed between the superstrate and the support surface for structurally securing the solar module to the frame.

27. A solar module assembly as set forth in claim 26 further including a gap between the guard and the solar module.

28. A solar module assembly as set forth in claim 27 further comprising a water barrier disposed in the gap.

29. A solar module assembly as set forth in claim 26 wherein the structural sealant comprises a structural adhesive.

30. A solar module assembly as set forth in claim 29 wherein the structural adhesive is selected from the group consisting of: acrylics, polyurethanes, epoxies, silicones and combinations thereof.

31. A solar module assembly as set forth in claim 26 wherein the structural sealant comprises a structural adhesive tape.

32. A solar module assembly as set forth in claim 26 wherein the structural sealant comprises hot melt sealant.

33. A solar module assembly as set forth in claim 26 wherein the support surface is flat.

34. A solar module assembly as set forth in claim 26 wherein the frame comprises at least a pair of frame members.

35. A solar module assembly as set forth in claim 26 wherein the frame is made of a material from the group consisting of metals, composites, plastics and combinations thereof.

36. A solar module assembly as set forth in claim 35 wherein the frame is molded to form a one-piece frame.

37. A method of making a solar module assembly comprising:
providing a solar module having a superstrate, a backing and at least one solar cell between the superstrate and the backing;
forming an integral frame having a support surface for supporting the solar module;
placing a structural sealant on the surface and placing the solar module on the structural sealant to thereby structurally secure the solar module to the frame.

38. A method as set forth in claim 37 wherein the structural sealant comprises a structural adhesive.

39. A method as set forth in claim 38 wherein the structural adhesive is selected from the group consisting of: acrylics, polyurethanes, epoxies, silicones and combinations thereof.

40. A method as set forth in claim 37 wherein the structural sealant comprises a structural adhesive tape.

41. A method as set forth in claim 37 wherein the structural sealant comprises hot melt sealant.

42. A method as set forth in claim 37 wherein the frame comprises at least a pair of frame members.

43. A method as set forth in claim 42 wherein the frame further comprises at least one brace member extending intermediate the at least pair of frame members.

44. A method as set forth in claim 43 further comprising forming an opening between brace members for receiving electrical components.

45. A method as set forth in claim 37 further comprising placing the structural sealant between the superstrate and the support surface.

46. A method as set forth in claim 45 wherein the frame further comprises a guard transverse to the support surface.

47. A method as set forth in claim 46 further comprising forming a gap between the solar module and the guard and placing a water barrier in the gap.

48. A method as set forth in claim 37 wherein the frame is formed by molding a one-piece frame.
